(19) United States
(12) Patent Application Publication
(10) Pub. No.: US 2014/0091782 A1
(43) Pub. Date: Apr. 3, 2014

(54) GALVANICALLY ISOLATED VOLTAGE MEASUREMENT

(71) Applicants: Ian Sykes, Bradford (GB); Paul Clay, Bradford (GB); Julia Szajdzicka, Bradford (GB)

(72) Inventors: Ian Sykes, Bradford (GB); Paul Clay, Bradford (GB); Julia Szajdzicka, Bradford (GB)

(73) Assignee: Northern Design (Electronics) Limited, Bradford, West Yorkshire (GB)

(21) Appl. No.: 14/113,220

(22) PCT Filed: Apr. 26, 2012
(86) PCT No.: PCT/GB2012/050913

§ 371 Date: Dec. 13, 2013

(30) Foreign Application Priority Data
Apr. 27, 2011 (GB) 1106980.4

(51) Int. Cl. G01R 15/14

(52) U.S. Cl. CPC G01R 15/144
USPC 324/76.11

(57) ABSTRACT

In a voltage measurement apparatus high—i.e. un-attenuated—voltages are connected to an attenuator 12, which then feeds attenuated voltage waveforms to a microprocessor-based analogue-digital converter/voltage measurement circuit 14. A representative digital voltage signal 16 and a synchronising signal 18 are then sent across an optical isolation barrier 20, and are then output to metering circuits 22. The metering circuits 22 receive analogue current inputs 24 which are sampled in synchronism with the digital voltage signals for an accurate measurement of power. Safe outputs 26 are provided which are isolated from any dangerous voltage.

The present invention relates to a method and apparatus for measuring voltage, and in particular as part of an energy metering system.

Currently in domestic and commercial premises energy use is measured using stand-alone meters. Particularly in commercial premises the electricity usage of several devices or appliances, hereinafter referred to generally as “loads”, is often monitored using separate meters for each load. In such cases, in order to derive valuable data about the energy usage of each load it is necessary to collate metered values manually, and subsequently enter the data manually on a computer for processing.

More sophisticated meters are configured to send data automatically to a data logging device which may be local, or may be reached via a communications device, for example over the telephone line, or the internet.

As well as measuring the current, which may be achieved for example by using a current transducer, an accurate measurement of voltage is needed to obtain an accurate value for the power consumption.

In a previously considered energy metering system it is customary to measure voltage using a resistive divider network connected directly to the voltages to be measured. The resistive network reduces the potentially dangerous voltages to a low level suitable for input to an electronic measuring system such as a microprocessor analogue to digital converter.

The voltages are measured in reference to the neutral level and it is usual for the electronic measuring system to be connected to this neutral voltage and have all its digital and analogue signals floating within a few volts of the neutral level. However, it is not considered safe to allow the user to have access to any conducting part of an item of equipment that may be connected to the neutral voltage.

This presents a problem to the designers of metering system in that any signals fed out of the measuring equipment, such as communications and pulse outputs, must be galvanically isolated within the metering equipment. This requirement adds complexity and cost to each individual output.

If the voltage measurement inputs were galvanically isolated at the level required to comply with global safety legislation then the measurement electronics (apart from the voltage measurement circuit) could be at a safe voltage and all outputs circuits could be connected directly to this circuit and still remain safe for access by the user.

One approach would be to isolate the measurement voltages using analogue transformers within the equipment. However, such a design would introduce measurement errors and would prove expensive to implement.

Preferred embodiments of the present invention aim to address at least some of the aforementioned shortcomings in the prior systems.

The present invention is defined in the attached independent claims, to which reference should now be made. Further, preferred features may be found in the sub-claims appended thereto.

According to one aspect of the present invention there is provided a method of measuring voltage comprising converting an analogue voltage waveform to a digital signal, representative of the analogue voltage waveform, transmitting the representative digital voltage signal across an isolation barrier and distributing the representative digital signal to a number of measurement devices.

Preferably the method includes attenuating the analogue voltage waveform prior to converting it into the representative digital voltage signal.

In a preferred arrangement the method comprises converting the analogue voltage waveform at a single first location and distributing the representative digital voltage signal to measurement devices at a plurality of second locations, at least some of which may be remote from said first location.

Preferably the method comprises transmitting to the number of measurement devices a synchronising signal, along with the representative digital voltage signal.

The method may comprise transmitting the representative digital voltage signal and the synchronising signal to measurement devices that comprise current measurement devices and derive power and/or other measurements.

The representative digital voltage signal may comprise a digital voltage data packet and, as an alternative or in addition, a synchronising signal for the measurement devices may comprise the start of the digital voltage data packet.

The method may form part of a method of measuring power consumption of a load and may include transmitting the representative digital voltage signal and a synchronising signal to an electricity meter which is arranged to measure current, and synchronising the current and voltage measurement to obtain a power measurement.

The invention also includes apparatus for measuring voltage comprising a converter for converting an analogue voltage waveform to a representative digital voltage signal, and an output arranged to provide the representative digital voltage signal to a number of measurement devices, wherein the output is separated from the converter by an isolation barrier.

In a preferred arrangement the apparatus is arranged in use to attenuate the analogue voltage waveform before it is converted into the representative digital voltage signal.

Preferably the output is arranged to provide the representative digital voltage signal to a number of measurement devices located remotely from the converter.

In a preferred arrangement the converter comprises a microprocessor. Preferably the microprocessor is arranged to generate a synchronising signal for the measurement devices. As an alternative, or in addition, a synchronising signal may be taken as the start of a digital data voltage packet in the representative digital voltage signal.

The measurement devices may comprise current measurement devices and derive power and/or other measurements.

In a preferred arrangement the output is arranged to provide a synchronising signal and the representative digital voltage signal to a plurality of power measurement devices located remotely from the converter, which use the synchronising signal to synchronise the measurement of electrical current with the voltage signal.

The isolation barrier may comprise an optical isolation barrier.

The invention may comprise any combination of the features or limitations referred to herein, except such a combination of features as are mutually exclusive.

A preferred embodiment of the present invention will now be described by way of example only, with reference to the accompanying diagrammatic drawings in which:

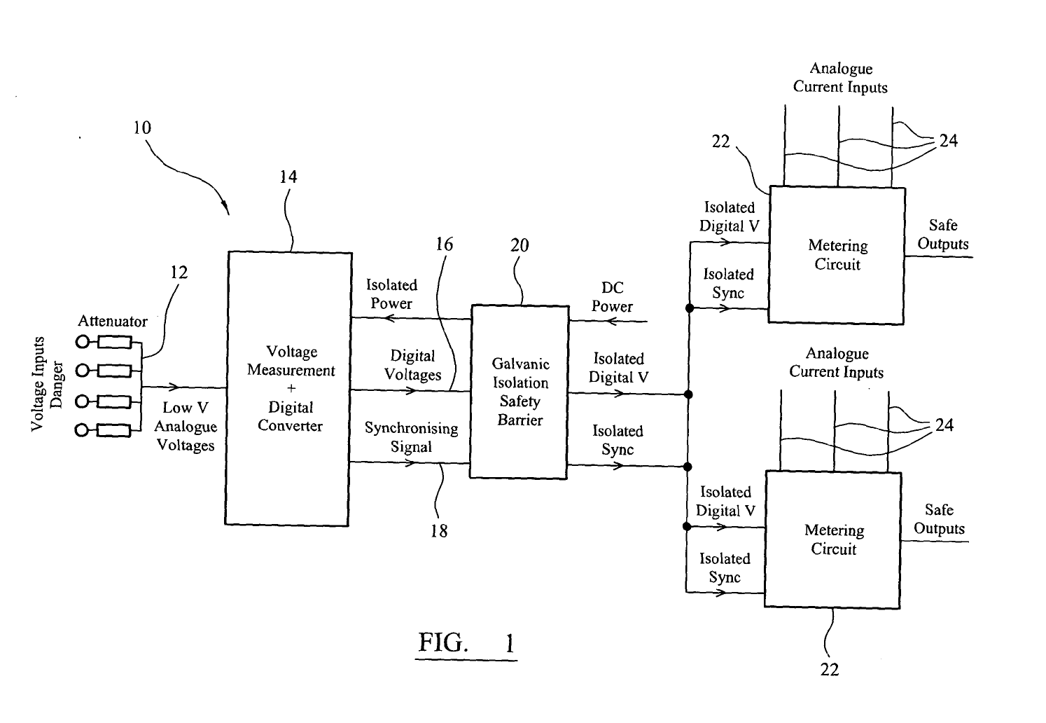

FIG. 1 is a schematic circuit diagram showing a voltage measurement apparatus, in accordance with an embodiment of the present invention.

The present invention relies upon the fact that digital signals can be transmitted across an isolation barrier (such as an optical isolation barrier) without loss of information. Embodiments of the present invention measure the voltages using a microprocessor circuit, local to the voltage measurement inputs—i.e local to the loads—to sample the voltage waveforms multiple times per power cycle. The microprocessor then sends a digital representation of the voltage waveforms, along with a synchronising signal, across a safety isolation barrier.

Referring to FIG. 1, there is shown, schematically generally at 10, an embodiment of voltage measurement apparatus, according to the invention.

High—i.e. un-attenuated—voltages are connected to attenuator 12, which then feeds attenuated voltage waveforms to a microprocessor-based analogue-digital converter/voltage measurement circuit 14. A representative digital voltage signal 16 and a synchronising signal 18 are then sent across an optical isolation barrier 20, and are then output to metering circuits 22. The metering circuits 22 receive analogue current inputs 24 which are sampled in synchronism with the digital voltage signals for an accurate measurement of power. Safe outputs 26 are provided which are isolated from any dangerous voltage.

Accuracy is determined by the microprocessor circuit local to the converter/voltage measurement circuit 14 and this is maintained by sending values numerically as bits/bytes across the isolation barrier 20. By tailoring the measurement circuit 14 to the application, ie the type of load (not shown), various levels of accuracy can be obtained.

The digital voltage values sent across the isolation barrier 20 may be picked up by a second microprocessor in the metering circuit 22 which can combine the values with samples of current waveforms and thus produce the same functionality of fully—featured, multiple—parameter power measurement devices.

The synchronising signal 18 allows the accurate combination of multiple samples of voltages and currents per input power cycle with no time shift. This is essential for an accurate determination of parameters such as kW.

In an alternative embodiment (not shown) the synchronising signal can be derived from the start of the digital voltage data packet. This advantageously removes the need for a separate synchronising signal, and hence only a single channel isolating barrier may be needed.

This accurate digital voltage isolation system can be used in other devices which require accurate voltage measurement such as digital voltage transducers which do not necessarily require current measurements.

The digitally isolated voltage signals can be simultaneously transmitted to a number of power meters 22 designed to take this form of voltage input. The individual meters are lower in complexity since they have no voltage measurement inputs, and therefore they are less expensive than previously considered devices. The transmission medium can be designed to suit transmission over short or long distances and can be wired, as shown in FIG. 1, or else can be wireless.

The isolation barrier 20 in the above example is an optical isolation barrier, but other types of isolation could be employed.

Whilst endeavouring in the foregoing specification to draw attention to those features of the invention believed to be of particular importance, it should be understood that the applicant claims protection in respect of any patentable feature or combination of features referred to herein, and/or shown in the drawings, whether or not particular emphasis has been placed thereon.

1. A method of measuring voltage comprising converting an analogue voltage waveform to a digital signal, representative of the analogue voltage waveform, transmitting the representative digital voltage signal across an isolation barrier and distributing the representative digital signal to a number of measurement devices.

2. A method according to claim 1, including attenuating the analogue voltage waveform prior to converting it into the representative digital voltage signal.

3. A method according to claim 1, comprising converting the analogue voltage waveform at a single first location and distributing the representative digital voltage signal to measurement devices at a plurality of second locations.

4. A method according to claim 1, comprising providing to the number of measurement devices a synchronising signal, along with the representative digital voltage signal.

5. A method according to claim 4, comprising providing the representative digital voltage signal and the synchronising signal to measurement devices that comprise voltage measurement devices or power measurement devices.

6. A method according to claim 1 in which the method forms part of a method of measuring power consumption of a load.

7. Apparatus for measuring voltage comprising a converter for converting an analogue voltage waveform to a representative digital voltage signal, and an output arranged to provide the representative digital voltage signal to a number of measurement devices, wherein the output is separated from the converter by an isolation barrier.

8. Apparatus according to claim 7, wherein the apparatus is arranged in use to attenuate the analogue voltage waveform before it is converted into the representative digital voltage signal.

9. Apparatus according to claim 7, wherein the output is arranged to provide the representative digital voltage signal to a number of measurement devices located remotely from the converter.

10. Apparatus according to claim 7, wherein the converter comprises a microprocessor.

11. Apparatus according to claim 10, wherein the microprocessor is arranged to generate a synchronising signal for the measurement devices.

12. Apparatus according to claim 7, wherein the or each measurement device comprises a voltage measurement device or a power measurement device.

13. Apparatus according to claim 11, wherein the output is arranged to provide the synchronising signal and the representative digital voltage signal to a plurality of power measurement devices located remotely from the converter, which use the synchronising signal to synchronise the measurement of electrical current with the voltage signal.

14. Apparatus according to claim 7, wherein the isolation barrier comprises an optical isolation barrier.
